(19) United States
(12) Patent Application Publication
(10) Pub. No.: US 2014/0320162 A1
(43) Pub. Date: Oct. 30, 2014

(54) WIRING STATE DETECTION DEVICE AND INTELLIGENT POWER MODULE

(71) Applicant: Keisuke HATA, Toyota-shi (JP)

(72) Inventor: Keisuke HATA, Toyota-shi (JP)

(73) Assignee: TOYOTA JIDOSHA KABUSHIKI KAISHA, Toyota-shi (JP)

(21) Appl. No.: 14/244,390

(22) Filed: Apr. 3, 2014

(30) Foreign Application Priority Data
Apr. 26, 2013 (JP) 2013-094313

(51) Int. Cl. G01R 31/40

(52) U.S. Cl. CPC G01R 31/40
USPC 324/764.01

(57) ABSTRACT

A wiring state detection device is configured to detect a state of a wiring that detachably and electrically connects a drive unit and a control unit via a connector. The drive unit has a switching element. The control unit is configured to perform drive control of the switching element. The wiring state detection device includes a phase delay detection unit and a connection state determination unit. The phase delay detection unit is configured to detect a phase delay of the drive of the switching element with respect to a command signal that the control unit supplies toward the switching element of the drive unit. The connection state determination unit is configured to determine whether or not a connection state of the connector or the wiring is normal based on whether or not the phase delay detected by the phase delay detection unit is less than a predetermined threshold.

### INCORPORATION BY REFERENCE

The disclosure of Japanese Patent Application No. 2013-094313 filed on Apr. 26, 2013 including the specification, drawings and abstract is incorporated herein by reference in its entirety.

### BACKGROUND OF THE INVENTION

1. Field of the Invention

The present invention relates to a wiring state detection device and an Intelligent Power Module (IPM).

2. Description of Related Art

A wiring state detection device that detects a state of wiring used in a power module has been known (see Japanese Patent Application Publication No. 2012-032359 (JP 2012-032359 A), for example). The power module includes a power drive unit that has a switching element and a control unit (control board) that performs drive control of an insulated gate bipolar transistor (IGBT) that is a switching element. The drive unit and the control unit are electrically connected via a wiring and electrically connected detachably with a connector.

The wiring state detection device includes a resistance disposed on an output stage of the control unit, an amplifier that amplifies a voltage generated between both ends of the resistance, and a comparison unit that compares an output signal of the amplifier with a predetermined threshold. The resistance is disposed on a flow passage of a gate signal of the IGBT and interposed between the output stage of the control unit and the IGBT of the drive unit. The wiring state detection device detects a state of the wiring that electrically connects the drive unit and the control unit via the connector by comparing an output signal from the amplifier obtained by amplifying a voltage generated between both ends of the resistance and a predetermined threshold with the comparison unit. Specifically, it is determined that short-circuiting is generated in the wiring when the output signal of the amplifier is higher than a reference voltage for disconnection detection as a predetermined threshold. Further, it is determined that the disconnection is generated in the wiring, when the output signal of the amplifier is lower than a reference voltage for disconnection detection as a predetermined threshold.

An IGBT gate resistance on a gate signal flow passage of the control unit generally has a relatively small resistance value. Therefore, in order to detect a voltage generated between both ends of a gate resistance in a device described in the JP 2012-032359 A, the voltage between the both ends of the gate resistance has to be amplified with a large gain. However, such a configuration is poor in efficiency when a state of the wiring that electrically connects between the control unit and the drive unit via a connector is detected. In addition, since the power module that uses the IGBT is generally driven under a high-voltage and a high current, it is more likely to erroneously detect the state of wiring due to large noise generated in the power module.

### SUMMARY OF THE INVENTION

The present invention provides a wiring state detection device that can efficiently and accurately detect a state of a wiring that electrically connects a control unit with a drive unit via a connector and an IPM.

A first aspect of the present invention is a wiring state detection device configured to detect a state of a wiring that detachably and electrically connects a drive unit and a control unit via a connector. The drive unit has a switching element. The control unit is configured to perform drive control of the switching element. The wiring state detection device includes a phase delay detection unit and a connection state determination unit. The phase delay detection unit is configured to detect a phase delay of the drive of the switching element with respect to a command signal that the control unit supplies toward the switching element of the drive unit. The connection state determination unit is configured to determine whether or not a connection state of the connector or the wiring is normal based on whether or not the phase delay detected by the phase delay detection unit is less than a predetermined threshold.

A second aspect of the present invention is an IPM. The IPM includes: a drive unit that has a switching element; a control unit configured to perform drive control of the switching element; a connector; a wiring that detachably and electrically connects the drive unit and the control unit via the connector; and a wiring state detection device that is configured to detect a state of the wiring and has a microcomputer. The microcomputer is configured to detect a phase delay of drive of the switching element with respect to a command signal that the control unit supplies toward the switching element of the drive unit. The microcomputer is configured to determine whether or not the connector or the wiring is in a normal connection state based on whether or not the phase delay is less than a predetermined threshold.

According to aspects of the present invention, a state of the wiring that electrically connects the control unit with the drive unit via the connector can be efficiently and accurately detected.

### BRIEF DESCRIPTION OF THE DRAWINGS

Features, advantages, and technical and industrial significance of exemplary embodiments of the present invention will be described below with reference to the accompanying drawings, in which like numerals denote like elements, and wherein:

FIG. 1 is a block diagram that shows an IPM of which wiring state is detected by a wiring state detection device according to a first embodiment of the present invention;

FIG. 2A and FIG. 2B each are a diagram that shows an operation wave form in the IPM of the present embodiment;

FIG. 3 is a flowchart that shows an example of a control routine that is executed in the wiring state detection device of the present embodiment;

FIG. 4 is a block diagram of the IPM of which wiring state is detected by the wiring state detection device of second embodiment of the present invention;

FIG. 5A and FIG. 5B each are a diagram that shows an operation waveform in the IPM of the present embodiment; and

FIG. 6 is a flowchart of an example of the control routine that is executed in the wiring state detection device of the present embodiment.

### DETAILED DESCRIPTION OF EMBODIMENTS

Hereinafter, specific embodiments of a wiring state detection device and an IPM of the present invention will be described with reference to the drawings.

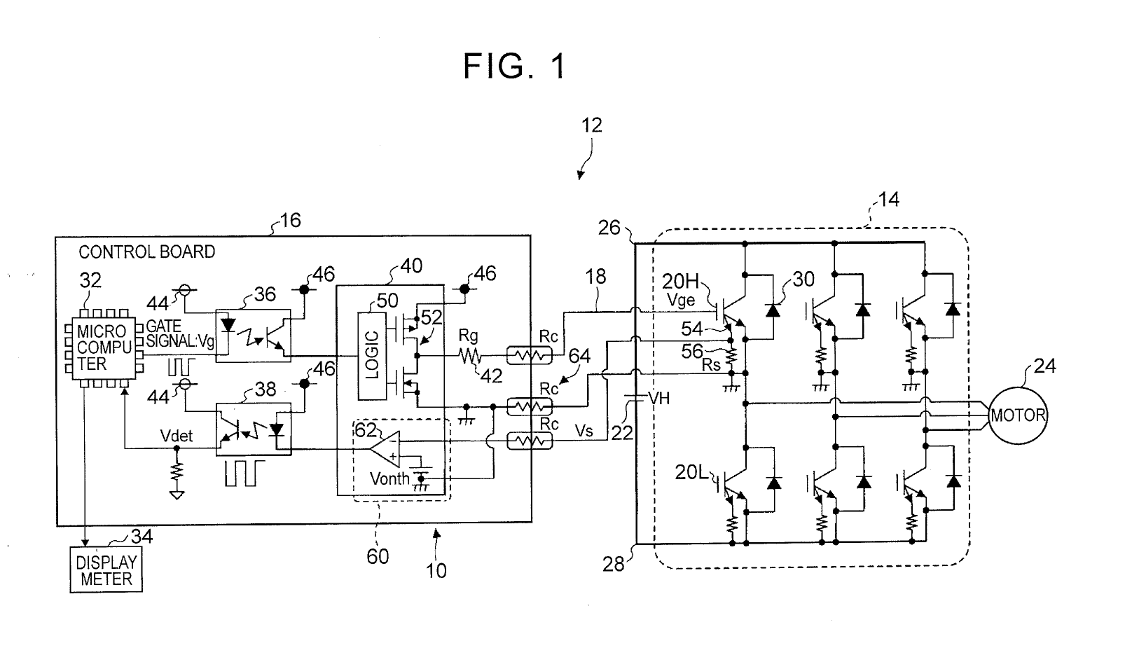

FIG. 1 shows a block diagram of an IPM 12 of which wiring state is detected by a wiring state detection device 10 that is a first embodiment of the present invention. The IPM 12 of the present embodiment is mounted on an electric vehicle or a hybrid vehicle, for example, and is a component that is used in an inverter that performs power conversion. As shown in FIG. 1, the IPM 12 includes a semiconductor module 14 constituted by a power semiconductor and a control board 16 that performs drive control of the power semiconductor. The semiconductor module 14 and the control board 16 are electrically connected via a wiring 18.

The semiconductor module 14 includes a switching element 20 that is switching-operated during power conversion. The switching element 20 is an insulated gate bipolar transistor (IGBT) that is a power semiconductor. The semiconductor module 14 is a power conversion unit that uses the switching element 20 and converts electric power of an external power source 22 that is an on-vehicle battery from a direct current to an alternate current and supplies to a motor 24.

The semiconductor module 14 is disposed between a high-voltage side terminal 26 and low-voltage side terminal 28 of the external power source 22. The semiconductor module 14 is an inverter circuit that converts DC electric power (output voltage VH) of the external power source 22 to AC electric power and outputs to the motor 24. The motor 24 a three-phase AC motor. The inverter circuit includes a pair of switching elements 20H and 20L disposed for each phase of a U phase, a V phase, and a W phase of the motor 24. In the inverter circuit, six switching elements 20 are bridge-connected between the high-voltage side terminal 26 and the low-voltage side terminal 28 of the external power source 22. In each of phases, the switching element 20H forms an upper arm connected to the high-voltage side terminal 26, and the switching element 20L forms a lower arm connected to the low-voltage side terminal 28.

The semiconductor module 14 includes also a reflux diode 30 that is parallel-connected between a collector and an emitter of the switching element 20. The reflux diode 30 is disposed for each of switching elements 20. The reflux diode 30 is a diode that allows a current to flow from an emitter-side to a collector-side of the switching element 20 and refluxes the current when a corresponding switching element 20 is turned off.

In the semiconductor module 14, each of the switching elements 20 and reflux diodes 30 is formed of a semiconductor chip that is formed into a thin rectangle. Further, the semiconductor module 14 is formed including a lead frame, a cooler, and a bus bar. The lead frame is a tabular metal plate on which the switching element 20 and the reflux diode 30 are disposed. The cooler cools the switching element 20 attached adjacently to the lead frame. The bus bar connects the terminal disposed to the lead frame to the high-voltage side terminal 26 or the low-voltage side terminal 28.

The control board 16 includes a microcomputer (hereinafter, simply referred to as micom) 32. The micom 32 includes a CPU, a ROM, and a RAM, and performs PWM control of each of drives of all switching elements 20 according to a program memorized in the ROM. The micom 32 outputs a binary gate signal Vg that changes to high or low in the range of 0V to 5V, for example, as a control signal that drives the switching element 20.

To the micom 32, a display meter 34 disposed in front of a driver's seat is connected. The micom 32 issues, on the display meter 34, a command for warning a vehicle occupant and calling attention to that connection abnormality may be generated in the IPM 12, when as described below, a connection state of the wiring 18 between the semiconductor module 14 and the control board 16 is determined not to be normal. The display meter 34 performs a warning and attention calling display according to a command from the micom 32.

The control board 16 includes also photocouplers 36 and 38, a control IC 40, and a gate resistance 42. The photocouplers 36 and 38, the control IC 40 and the gate resistance 42 are disposed for each of the switching elements 20. In FIG. 1, only what performs drive control of a switching element 20H-U on a U-phase upper arm side is shown, and, hereinafter, the switching element 20H-U on the U-phase upper arm side will be mainly described.

An input side of the photocoupler 36 is connected to an output side of the micom 32. Further, a first power source (a 5V power source that outputs 5V, for example) 44 is connected to an input side of the photocoupler 36. To the output side of the photocoupler 36, a second power source (a 15V floating power source that outputs 15V, for example) 46 electrically insulated from the first power source 44 is connected and the control IC 40 is connected. The photocoupler 36 is an element that transmits a gate signal Vg from the micom 32 to the control IC 40 by means of light while electrically insulating.

The control IC 40 includes a logic portion 50 and a CMOS portion 52. The control IC 40 is a drive circuit that uses electric power of the second power source 46 and reverses a signal level of the gate signal Vg transmitted from the photocoupler 36 and outputs. The gate resistance 42 described above is interposed between the output side of the control IC 40 and the gate of the switching element 20. The control signal output from the control IC 40 of the control board 16 is stepped down by a resistance value Rg of the gate resistance 42 and supplied to the switching element 20 of the semiconductor module 14 via the wiring 18 (a signal between gate and emitter: Vge). The switching element 20 is switching-operated according to the control signal from the control IC 40 of the control board 16.

The switching element 20 includes a sense emitter 54 that branches a collector current. The sense emitter 54 branches the collector current into a very small current (a current of one several thousandths relative to a total emitter current, for example). A current sense resistance 56 is connected to the sense emitter 54. The current sense resistance 56 has a resistance value of Rs and a function of converting a sense current flowing to the sense emitter 54 to a sense voltage Vs, that is, a function of extracting as an emitter voltage. The sense voltage Vs that is obtained by converting the sense current by the current sense resistance 56 of the semiconductor module 14 is supplied to the control IC 40 of the control board 16 via the wiring 18.

The control IC 40 includes a transmission detection circuit 60. The transmission detection circuit 60 includes a comparator 62. The sense voltage Vs is input from the semiconductor module 14 to a non-inversion input terminal of the comparator 62. A predetermined threshold voltage Vsth is input to the non-inversion input terminal of the comparator 62. The predetermined threshold voltage Vsth is the minimum voltage value generated between both ends of the current sense resistance 56 when the switching element 20 is determined to be fully turned on. The comparator 62 is a circuit that compares the sense voltage Vs from the semiconductor module 14 with the predetermined threshold voltage Vsth and outputs a binary transmission detection signal that changes between high and low.

An input side of the photocoupler 38 is connected to an output side of the comparator 62 of the transmission detection circuit 60 of the control IC 40. The second power source 46 is connected to the input side of the photocoupler 38. The first power source 44 and the input side of the micom 32 are connected to the output side of the photocoupler 38. The photocoupler 38 is an element that transmits the transmission detection signal from the comparator 62 to the micom 32 by means of light while electrically insulating.

The IPM 12 includes a connector 64 that electrically connects the semiconductor module 14 and the control board 16 via the wiring 18. The connector 64 is a terminal pin or a connector that detachably and electrically connects the semiconductor module 14 and the control board 16. The wiring 18 that electrically connects the semiconductor module 14 and the control board 16 is set such that a wiring length thereof has a distance as short as possible.

The micom 32 has a function as the wiring state detection device 10 that detects a state of the wiring 18 that electrically connects the semiconductor module 14 and the control board 16 on the basis of the transmission detection signal (emitter current detection signal) Vdet transmitted from the photocoupler 38. Specifically, the micom 32 measures a time (delay time) Td from a timing when the gate signal Vg that is a control signal that drives the switching element 20 is output (specifically, an on command timing) to a timing when the transmission detection signal Vdet transmitted from the photocoupler 38 is received after the sense voltage Vs has reached the predetermined threshold voltage Vsth (specifically, a timing when energization starts after the switching element 20 is turned on). Then, a state of the wiring 18, that is, a connection state of the connector 64 is detected by comparing the measured delay time Td with the predetermined threshold time Tx.

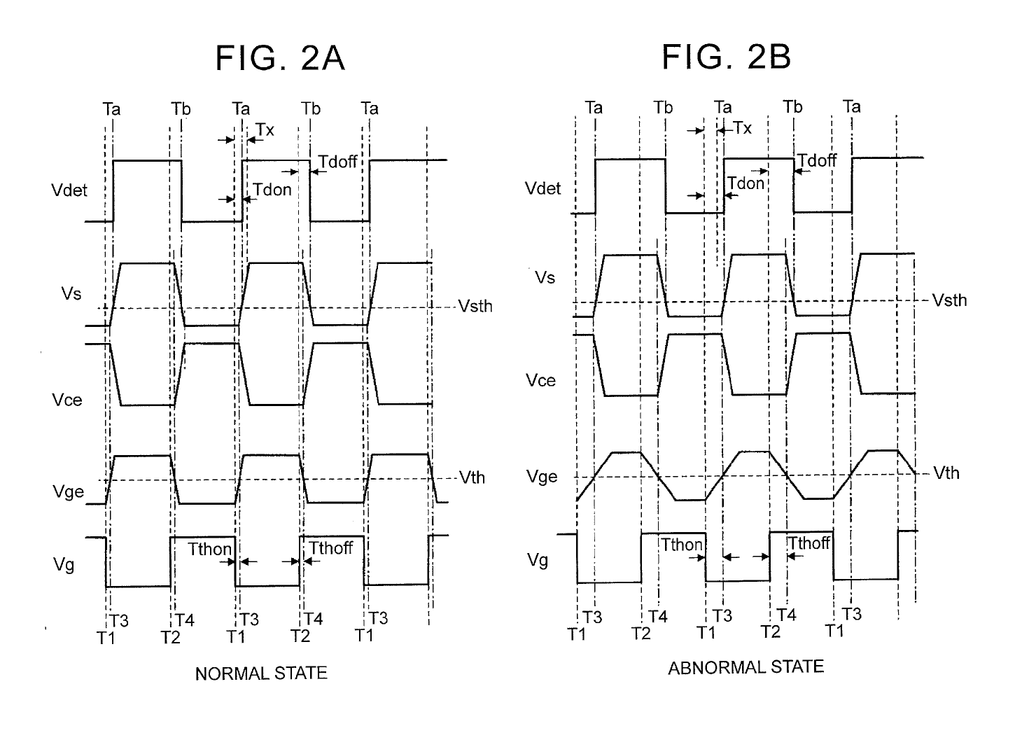

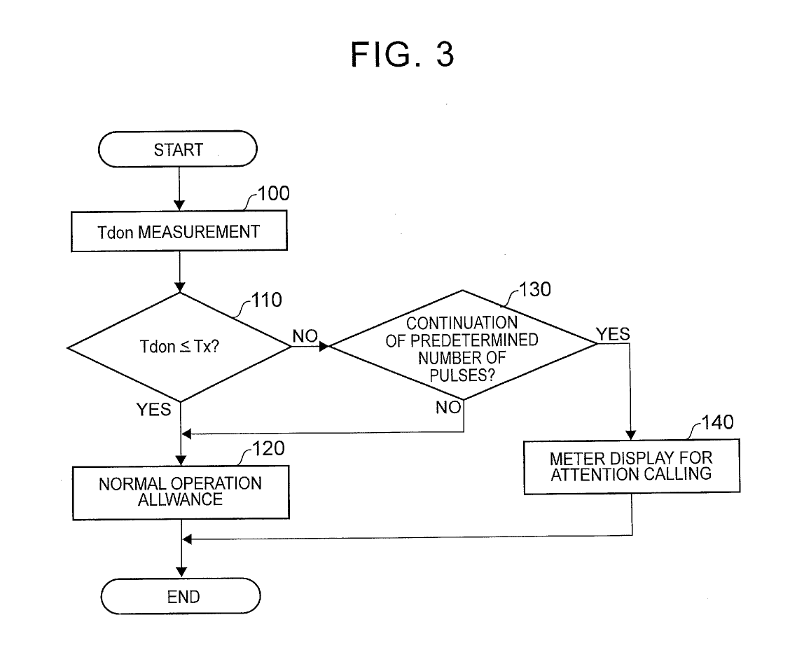

FIG. 2A and FIG. 2B show a diagram that shows an operation wave form in the IPM 12 of the present embodiment. FIG. 2A shows an operation wave form in a normal connection state, and FIG. 2B shows an operation waveform in an abnormal connection state. Further, FIG. 3 shows a flowchart of an example of a control routine that the micom 32 executes in the wiring state detection device 10 of the present embodiment.

In FIG. 2A and FIG. 2B, an on-command timing when the micom 32 outputs the gate signal Vg that turns on the switching element 20 is set to T1. An off command timing when the micom 32 outputs the gate signal Vg that turns off the switching element 20 is set to T2. An on start timing when the switching element 20 is switched from off to on after a state where a signal Vge between gate and emitter falls below the threshold Vth is shifted to a state that exceeds the threshold Vth is set to T3. An off start timing when the switching element 20 is switched from on to off after a state where the signal Vge between gate and emitter exceeds the threshold Vth is shifted to a state where the signal Vge falls below the threshold Vth is set to T4. An energization start timing when the energization from the collector to the emitter starts after the switching element 20 is fully turned on is set to Ta. A shutoff start timing when shutoff of the energization from the collector to the emitter starts after the switching element 20 is not sufficiently turned on is set to Tb.

Further, a delay time from the on command timing T1 of the micom 32 to the on start timing T3 of the switching element 20 is set to Tthon. A delay time from the off command timing T2 of the micorn 32 to the off start timing T4 of the switching element 20 is set to Tthoff. A delay time from the on command timing T1 of the micom 32 to the energization start timing Ta of the switching element 20 is set to Tdon. A delay time from the off command timing T2 of the micom 32 to shutoff start timing Tb of the switching element 20 is set to Tdoff. The threshold time of the delay times Tdon and Tdoff are set to Tx.

In the present embodiment, the micom 32 of the control board 16 performs switching drive of a switching element 20H on an upper arm side and a switching element 20L on a lower arm side of each of phases of the semiconductor module 14 in a reversed phase with each other. Furthermore, the micom 32 of the control board 16 performs switching drive of the switching element 20 of U phase, V phase and W phase by shifting by a predetermined phase difference.

In the present embodiment, when the micom 32 outputs the gate signal Vg that turns on the switching element 20 (on command timing T1), a signal Vge between gate and emitter corresponding to the gate signal Vg is supplied from the control IC 40 to the switching element 20 of the semiconductor module 14. At this time, the signal Vge between gate and emitter is transmitted delayed with respect to the gate signal Vg by a time constant corresponding to a resistance (mainly gate resistance 42) and capacitance (mainly gate capacitance) on a flow passage.

Then, when the signal Vge between gate and emitter exceeds the threshold Vth of the switching element 20 (on start timing T3), the switching element 20 is switched from off to on, a voltage Vice between collector and emitter of the switching element 20 decreases, the collector current Ic starts flowing to the emitter, and a sense voltage Vs gradually rises. As a result, when the sense voltage Vs exceeds the predetermined threshold voltage Vsth, the switching element 20 is fully turned on and the emitter current flows (energization start timing Ta).

Further, when the micom 32 of the control board 16 outputs the gate signal Vg that turns off the switching element 20 (off command timing T2), the signal Vge between gate and emitter corresponding to the gate signal Vg is supplied from the control IC 40 to the switching element 20 of the semiconductor module 14.

Then, the signal Vge between gate and emitter falls below the threshold Vth of the switching element 20 (off start timing T4), the switching element 20 is switched from on to off, a voltage Vice between collector and emitter of the switching element 20 rises, a flow of the collector current Ic to the emitter starts to be suppressed, and the sense voltage Vs gradually decreases. As a result, when the sense voltage Vs falls below the predetermined threshold voltage Vsth, the switching element 20 is not sufficiently turned on, and a flow of the emitter current is stopped (shutoff start timing Tb).

Thus, when the switching element 20H on an upper arm side and a switching element 20L on a lower arm side of each of phases of the semiconductor module 14 are switching driven in reversed phases with each other and the switching elements 20 of U phase, V phase and W phase are switching driven by shifting by a predetermined phase difference, DC electric power of the external power source 22 is converted into AC electric power and supplied to the motor 24. Therefore, the motor 24 is properly rotationally driven.

Further, when the switching element 20 is sufficiently turned on at the energization start timing Ta as described above, the transmission detection signal Vdet corresponding to on of the switching element 20 is output from the control IC 40 and input in the micom 32. When the micom 32 receives the transmission detection signal Vdet that shows on of the switching element 20 after the gate signal Vg that turns on the switching element 20 has been output, a delay time Tdon from the on command timing T1 when the gate signal Vg is output to the energization start timing Ta when the micom 32 has received the transmission detection signal Vdet that shows on of the switching element 20 is measured (step 100).

The micom 32 determines whether or not the delay time Tdon measured as shown above is within the predetermined threshold time Tx (step 110). The predetermined threshold time Tx is the longest delay time Tdon when a state of the wiring 18 that connects the control board 16 and the semiconductor module 14, that is, a connection state of the connector 64 is determined to be in a normal state. Further, the predetermined threshold time Tx may be set to between an actual dead time and allowable dead time that is allowed as the semiconductor module 14, after the actual dead time generated between the switching elements 20H and 20L of the upper and lower arms has been learned, and is set to a predetermined value.

As described above, the signal Vge between gate and emitter is transmitted delayed by a time constant corresponding to resistance and capacitance on the flow path with respect to the gate signal Vg. On the other hand, when a connection state of the wiring 18 or the connector 64 is degraded due to aging of the connector 64, contact resistance Rc in the connector 64 increases. When such contact resistance Re increases, the time constant increases according to the increment amount of the contact resistance Rc, and a phase delay of the signal Vge between gate and emitter becomes larger with respect to the gate signal Vg. Therefore, on the basis of the magnitude of such phase delay, a state of the wiring 18 that electrically connects the control board 16 and the semiconductor module 14 via the connector 64 can be detected.

The micom 32 determines that the wiring 18 is in a normal state and the connector 64 properly electrically connects the control board 16 and the semiconductor module 14, when in step 110 the delay time Tdon is determined to be within the predetermined threshold time Tx, and allows an operation as usual (step 120).

On the other hand, the micom 32 determines that the wiring 18 is not in a normal state but a connection abnormality may be generated in the connector 64, when the delay time Tdon is determined to exceed the predetermined threshold time Tx in the step 110. Then, whether or not the phenomenon is continuously generated exceeding the predetermined number of pulses (five pulses, for example) is determined (step 130).

As a result thereof, an operation as usual is allowed when the phenomenon where the delay time Tdon exceeds the predetermined threshold time Tx is determined not to continue more than the predetermined number of pulses (step 120). On the other hand, on the display meter 34, a command for warning a vehicle occupant and calling attention to that abnormality of the wiring 18 may be generated is issued, when the phenomenon where the delay time Tdon exceeds the predetermined threshold time Tx is determined to continue the predetermined number of pulses (step 140). In this case, the display meter 34 performs warning and attention calling display according to the command from the micom 32. For example, as the display example, “A connection state of the connector has changed.” or “Maintenance of the IPM is necessary.” can be used.

Thus, in the wiring state detection device 10 of the present embodiment, a phase delay of the signal Vge, with respect to the gate signal Vg, between gate and emitter by which the switching element 20 is driven is detected as the delay time Tdon. The micom 32 of the control board 16 supplies the gate signal Vg toward the switching element 20 of the semiconductor module 14. Thus, a state of the wiring 18 that electrically connects the control board 16 and the semiconductor module 14 via the connector 64 can be detected based on whether or not the delay time Tdon is within the predetermined threshold time Tx.

The wiring 18 can be determined to be in a normal state, when the delay time Tdon is within the predetermined threshold time Tx as shown in FIG. 2A. On the other hand, the wiring 18 can be determined to may not be in a normal state, when the delay time Tdon exceeds the predetermined threshold time Tx as shown in FIG. 2B.

Even if the delay time Tdon exceeds the predetermined threshold time Tx, each of the switching elements 20 can be driven, therefore, the motor 24 can be operated. Thus, before the operation of the motor 24 becomes impossible, it is possible to notify a vehicle user that the wiring 18 or the connector 64 may not be in a normal state, that is, a failure sign of the motor 24, through the display meter 34. Therefore, according to the wiring state detection device 10 of the present embodiment, it is possible to urge exchange or repair of the wiring 18 that electrically connects the control board 16 with the semiconductor module 14 via the connector 64 or the connector 64 thereof, before occurrence of inoperability of the motor 24.

Now, the determination that the wiring 18 may not be in a normal state in the present embodiment is executed specifically when the phenomenon that the delay time Tdon exceeds the predetermined threshold time Tx has continuously occurred by the predetermined number of pulses during turn-on of the switching element 20. Therefore, according to the present embodiment, the determination that the connection abnormality occurs in the wiring 18 or the connector 64 can be accurately performed.

Further, in the present embodiment, a current that flows to the sense emitter 54 of the switching element 20, that is, a voltage (that is, emitter voltage) that is generated between both ends of a current sense resistance 56 connected to the sense emitter 54 is compared with a threshold value. Then, a state of the wiring 18 is detected by using a phase delay (that is, delay time Tdon) of the transmission detection signal Vdet based on the comparison result with respect to the gate signal Vg output from the micom 32.

Therefore, according to the present embodiment, it is unnecessary to amplify a voltage between both ends of the resistance with a large gain different from a case where a voltage between both ends of the gate resistance 42 is used to detect a state of the wiring 18. Further, an erroneous detection of the wiring state due to a large noise generated in the IPM 12 can be prevented. Therefore, according to the present embodiment, a state of the wiring 18 that electrically connects the control board 16 with the semiconductor module 14 via the connector 64 can be efficiently and accurately detected.

Still further, as described above, the sense emitter 54 branches the collector current of the switching element 20 into very small currents (current of one several thousandth to a total emitter current, for example). Thus, according to the present embodiment, it is not necessary to make a resistance value of the resistance (specifically, the current sense resistance 56 in the present embodiment) that is used to detect the emitter current very small compared with that in a configuration that directly detects the total emitter current to detect the emitter voltage. Also in this point, it is unnecessary to amplify the voltage between both ends of the resistance with a large gain, in addition, an erroneous detection of the wiring state due to a large noise generated in the IPM 12 can be prevented. Therefore, according to the present embodiment, a state of the wiring 18 that electrically connects the control board 16 with the semiconductor module 14 via the connector 64 can be efficiently and accurately detected.

Further, as a means for preventing an erroneous detection of the wiring state due to a large noise generated in the IPM 12, it is considered to use a filter that has a large time constant on a flow passage of the gate signal from the output side of the micom 32 to the input side of the switching element 20. However, such a method takes much time to determine a state detection of the wiring, because the signal transmission takes relatively much time.

On the other hand, in the present embodiment, it is not necessary to make the resistance value of the gate resistance 42 on the gate signal flow passage between the output side of the micom 32 and the input side of the switching element 20 excessively large for detecting a state of the wiring 18 and it is unnecessary to dispose a filter having a large time constant. Therefore, according to the present embodiment, the state detection of the wiring 18 can be speedily determined because it does not take so much time to perform the signal transmission when the state detection of the wiring 18 is performed.

Now, in the first embodiment described above, the semiconductor module 14 can be assumed as a drive unit of the present invention. Further, the control board 16 can be assumed as a control unit of the present invention. That the micom 32 measures the delay time Tdon from the on command timing T1 when the gate signal Vg that turns on the switching element 20 is output to the energization start timing Ta when the transmission detection signal Vdet that shows on of the switching element 20 is received can be assumed as a phase delay detection unit of the present invention. Further, that the micom 32 determines whether or not a connection state of the wiring 18 or the connector 64 is normal based on whether or not Tdon Tx is satisfied can be assumed as a connection state determination unit of the present invention. The current sense resistance 56 can be assumed as a resistance and sense resistance of the present invention. Further, that the transmission detection circuit 60 detects a voltage obtained by voltage conversion of the sense current that flows the sense emitter 54 with the current sense resistance 56 as an output current of the switching element 20 can be assumed as an output current detection unit of the present invention. The transmission detection circuit 60 is disposed on the control board 16 side in the control IC 40. Further, the comparator 62 of the transmission detection circuit 60 can be assumed as a comparison unit of the present invention. Still further, that the micom 32 measures the delay time Tdon may be assumed as a delay time measurement unit of the present invention.

Further, although, in the first embodiment, the emitter current that flows to an output stage of the switching element 20 is indirectly detected by converting the sense current that flows to the sense emitter 54 into an emitter voltage with the current sense resistance 56, the present invention is not limited to the configuration. The present invention includes an embodiment in which a current sensor is disposed on the emitter side of the switching element 20 to detect the emitter current without using the sense emitter 54.

In the first embodiment, for detecting a state of the wiring 18, the delay time Tdon from the on command timing T1 when the micom 32 outputs the gate signal Vg that turns on the switching element 20 is output to the energization start timing Ta when the micom 32 receives the transmission detection signal Vdet that shows on of the switching element 20 is measured, and the delay time Tdon is compared with the predetermined threshold time Tx. However, the present invention is not limited to the configuration. The present invention includes an embodiment in which: the delay time Tdoff from the off command timing T2 when the micom 32 outputs the gate signal Vg for off command to the shutoff start timing Tb when the micom 32 receives the transmission detection signal Vdet that shows off of the switching element 20 is measured; and the delay time Tdoff is compared with the predetermined threshold time Tx. Further, both of these delay times Tdon and Tdoff may be compared with the predetermined threshold time Tx.

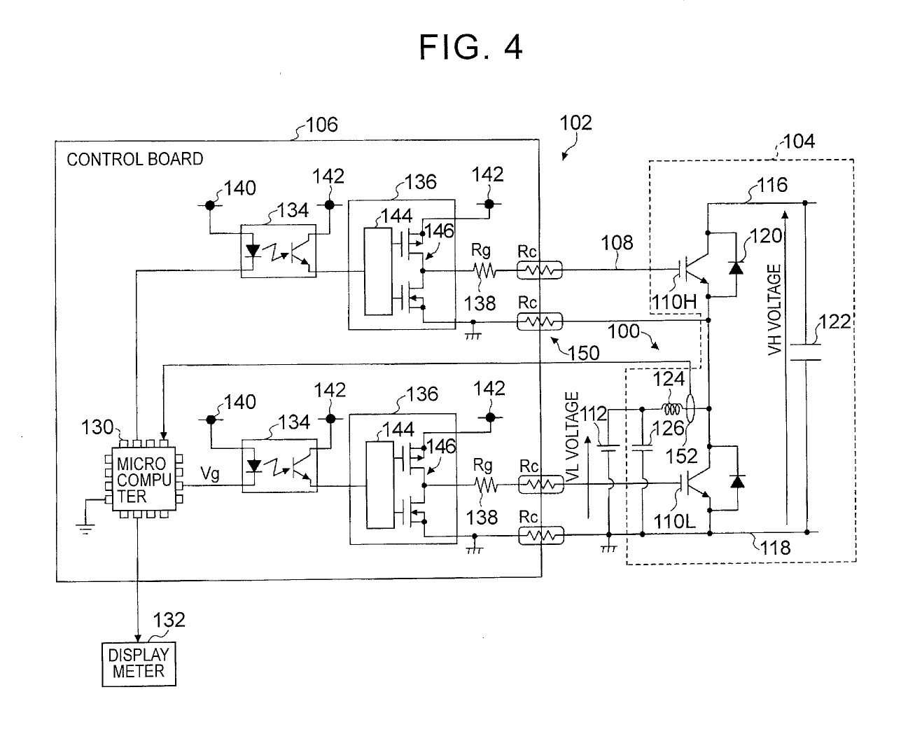

FIG. 4 is a block diagram of the IPM 102 in which a wiring state is detected by the wiring state detection device 100 according to the second embodiment of the present invention. The IPM 102 of the present embodiment is a component that is mounted on an electric vehicle or a hybrid vehicle, for example, and is used in a step-up converter that converts an output voltage of an external power source that is an on-vehicle battery. As shown in FIG. 4, the IPM 102 includes the semiconductor module 104 formed of a power semiconductor and the control board 106 that performs drive control of the power semiconductor. The semiconductor module 104 and the control board 106 are electrically connected via the wiring 108.

The semiconductor module 104 includes the switching element 110 that is switching-operated during the stepping-up operation. The switching element 110 is an IGBT (insulated gate bipolar transistor) that is a power semiconductor. The semiconductor module 104 is a stepping-up conversion unit that uses the switching element 110, performs a stepping-up conversion of an output voltage VL of an external power source 112 that is an on-vehicle battery, and supplies to a load.

The semiconductor module 104 includes a pair of switching elements 110H and 110L that are connected in series between a high-voltage side terminal 116 and a low-voltage side terminal 118. The switching element 110 is formed of a pair of switching elements 110H and 110L. The switching element 110H forms an upper arm that is connected to the high-voltage side terminal 116 and the switching element 110L forms a lower arm connected to the low-voltage side terminal 118. Between a collector and an emitter of each of the switching elements 110H and 110L, reflux diodes 120 that allow a flow of current from the emitter side to the collector side are connected in parallel. Further, a smoothing capacitor 122 on the secondary side is connected between the high-voltage side terminal 116 and the low-voltage side terminal 118.

In the semiconductor module 104, each of the switching elements 110 and the reflux diodes 120 is formed with a semiconductor chip that is formed into a thin rectangle. Further, the semiconductor module 104 is formed by including a lead frame, a cooler, and a bus bar. The lead frame is a tabular metal plate on which the switching element 110 and the reflux diode 120 are disposed. The cooler cools the switching element 110 attached adjacently to the lead frame. The bus bar connects the terminal disposed to the lead frame to the high-voltage side terminal 116 or the low-voltage side terminal 118.

The semiconductor module 104 further includes a reactor 124. The reactor 124 is inserted between a common connection point of the pair of switching elements 110H and 110L and a positive electrode terminal of the external power source 112. To the external power source 112, smoothing capacitors 126 on a primary side are connected in parallel. The reactor 124 has an operation of releasing and storing electric power when a voltage conversion is performed between a primary side voltage (that is, a voltage VL on the external power source 112 side) and a secondary side voltage (that is, a voltage VH between the high-voltage side terminal 116 and the low-voltage side terminal 118) of the IPM 102.

Further, the control board 106 includes a micom 130. The micom 130 includes a CPU, a ROM, and a RAM, and performs PWM control of each of all drives of all switching elements 110 according to a program stored in the ROM. The micom 130 outputs a binary gate signal Vg that changes to high and low in the range of 0 V to 5 V, for example, as a control signal that drives the switching element 110.

A display meter 132 disposed in front of a driver's seat is connected to the micom 130. The micom 130 issues, as described below, on a display meter 132, a command for warning a vehicle occupant and calling attention to that a connection abnormality may occur in the IPM 102, when a connection state of the wiring 108 between the semiconductor module 104 and the control board 106 is determined to be not in a normal state. The display meter 132 performs display for warning and calling attention according to a command from the micom 130.

The control board 106 further includes a photocoupler 134, a control IC 136, and a gate resistance 138. The photocoupler 134, control IC 136, and gate resistance 138 are disposed for every switching elements 110H and 110L.

An input side of the photocoupler 134 is connected to an output side of the micom 130. Further, a first power source (a 5 V power source that outputs 5 V, for example) 140 is connected to an input side of the photocoupler 134. To an output side of the photocoupler 134, a second power source (a 15 V floating power source that outputs 15 V, for example) 142 that is electrically insulated from the first power source 140 is connected and the control IC 136 is connected. The photocoupler 134 is an element that transmits the gate signal Vg from the micom 130 to the control IC 136 by means of light while electrically insulating.

The control IC 136 includes a logic unit 144 and a CMOS unit 146. The control IC 136 is a drive circuit that reverses a signal level of the gate signal Vg transmitted from the photocoupler 134 and outputs by means of the electric power of the second power source 142. The gate resistance 138 described above is interposed between the output side of the control IC 136 and a gate of the switching element 110. A control signal output from the control IC 136 of the control board 106 is stepped down by a resistance value Rg of the gate resistance 138 and supplied to the switching element 110 of the semiconductor module 104 via the wiring 108 (signal between gate and emitter: Vge). The switching element 110 is switching-operated according to a control signal from the control IC 136 of the control board 106.

The IPM 102 includes a connector 150 that electrically connects the semiconductor module 104 and the control board 106 via the wiring 108. The connector 150 is a terminal pin or a connector that electrically and detachably connects the semiconductor module 104 and the control board 106. The wiring 108 that electrically connects the semiconductor module 104 and the control board 106 is set such that a wiring length thereof has a distance as short as possible.

The IPM 102 includes a stepping-up current sensor 152. The stepping-up current sensor 152 is a sensor made of resistance and so on and outputs a signal corresponding to a current Ir that flows to the reactor 124. An output signal of the stepping-up current sensor 152 is supplied to the micom 130. The micom 130 detects the current Ir that flows to the reactor 124 on the basis the output signal from the stepping-up current sensor 152.

The micom 130 has a function as the wiring state detection device 100 that detects a state of the wiring 108 that electrically connects the semiconductor module 104 and the control board 106 on the basis of a signal supplied from the stepping-up current sensor 152. Specifically, the micom 130 measures a time (delay time) Tth from a timing (specifically, on-command timing) when the gate signal Vg that is a control signal that drives the switching element 110 is output to a timing (specifically, a timing when the switching element 110H or 110L is turned on and energization starts) when a signal from the stepping-up current sensor 152 is received. Then, a connection state of the wiring 108, that is, a connection state of the connector 150 is detected by comparing the measured delay time Tth with a predetermined threshold time Ty.

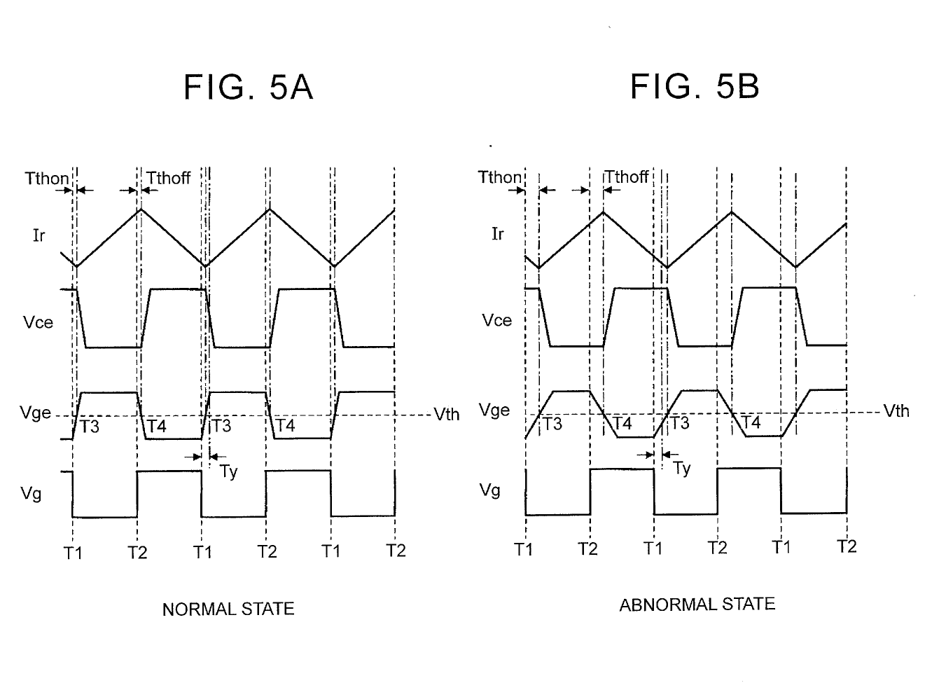

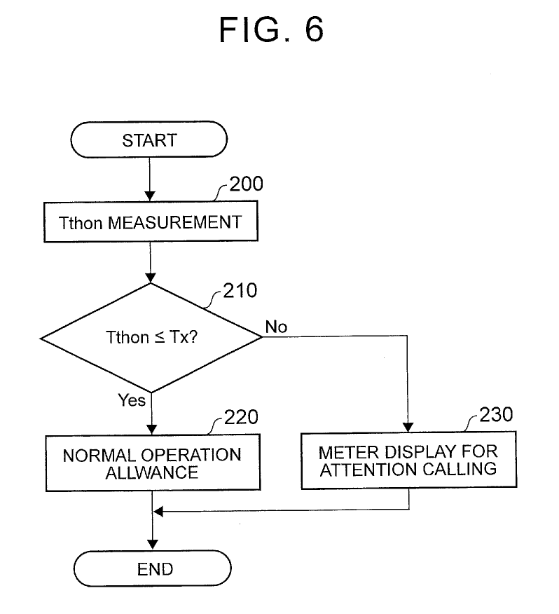

FIG. 5A and FIG. 5B show a diagram that shows an operation waveform in the IPM 102 of the present embodiment. FIG. 5A and FIG. 5B respectively show a normal connection state and an abnormal connection state. Further, FIG. 6 shows a flowchart of an example of the control routine executed by the micom 130 in the wiring state detection device 100 of the present embodiment.

In FIG. 5A and FIG. 5B, an on command timing when the micom 130 outputs the gate signal Vg that turns on the switching element 110L is set to T1. An off command timing when the micom 130 outputs the gate signal Vg that turns off the switching element 110L is set to T2. An on start timing when the switching element 110L is switched from off to on after the signal Vge between gate and emitter shifts from a state that falls below the threshold value Vth to a state that exceeds the threshold Vth is set to T3. An off start timing when the switching element 110L is switched from on to off after the signal Vge between gate and emitter shifts from a state that exceeds the threshold Vth to a state that falls below the threshold Vth is set to T4. A delay time from the on command timing T1 of the micom 130 to the on start timing T3 of the switching element 110L is set to Tthon. A delay time from the off command timing T2 of the micom 130 to the off start timing T4 of the switching element 110L is set to Tthoff. A threshold time of the delay times Tthon and Tthoff described above is set to a threshold time Ty.

In the present embodiment, the micom 130 of the control board 106 performs switching drive of the switching element 110H on an upper arm side and the switching element 110L on a lower arm side in reversed phases with each other.

In the present embodiment, when the micom 130 outputs the gate signal Vg that turns on the switching element 110L (on-command timing T1), the signal Vge between gate and emitter corresponding to the gate signal Vg is supplied from the control IC 136 to the switching element 110L of the semiconductor module 104. At this time, the signal Vge between gate and emitter is transmitted delayed by a time constant corresponding to the resistance (mainly gate resistance 138) and capacitance (mainly gate capacitance) on the flow passage with respect to the gate signal Vg.

Then, when the signal Vge between gate and emitter exceeds the threshold Vth of the switching element 110L (on start timing T3), the switching element 110L is switched from off to on, a voltage Vice between collector and emitter of the switching element 110L decreases, a collector current Ic begins to flow to the emitter, and a current Ir flowing to the reactor 124 gradually increases. When the switching element 110L is turned on, since the switching element 110H is turned off, the reactor 124 stores electric power due to flow of the current Ir. At this time, electric power is supplied from the smoothing capacitor 122 on the secondary side to a load connected between the high-voltage side terminal 116 and the low-voltage side terminal 118.

Further, when the micom 130 outputs the gate signal Vg that turns off the switching element 110L (off command timing T2), the signal Vge between gate and emitter corresponding to the gate signal Vg is supplied from the control IC 136 to the switching element 110L of the semiconductor module 104.

Then, when the signal Vge between gate and emitter falls below the threshold Vth of the switching element 110L (off start timing T4), the switching element 110L is switched from on to off, the voltage Vice between collector and emitter of the switching element 110L rises and a flow of the collector current Ic to the emitter is began to be suppressed, and the current Ir that flows to the reactor 124 gradually decreases. When the switching element 110L is turned off, since the switching element 110H is turned on, a current flows from the reactor 124 through the switching element 110H to the load side. In this case, since the electric power that is stored in the reactor 124 is released, the electric power is supplied to the load and the smoothing capacitor 122 on the secondary side is charged.

Thus, when the switching elements 110H and 110L of the semiconductor module 104 are switching driven in opposite phases with each other, and an output voltage of the external power source 112 is stepped-up and supplied to the load, the load is operated at a voltage higher than the output voltage of the external power source 112.

Further, as described above, when the switching element 20 is turned on at the on start timing T3, the current Ir that flows to the reactor 124 gradually increases. At this time, the output signal of the stepping-up current sensor 152 is input to the micom 130. The micom 130 measures the delay time Tthon when a signal that shows a current increase from the stepping-up current sensor 152 is received, after the gate signal Vg that turns on the switching element 110L is output (step 200). The delay time Tth is a time from the on command timing T1 when the gate signal Vg is output to the on start timing T3 when the switching element 110L is switched from off to on after a state where the signal Vge between gate and emitter falls below the threshold Vth shifts to a state where the gate signal Vge between gate and emitter exceeds the threshold Vth.

The micom 130 determines whether or not the delay time Tthon measured as described above is within the predetermined threshold time Ty (step 210). The predetermined threshold time Ty is the longest delay time Tthon when a state of the wiring 108 that connects the control board 106 and the semiconductor module 104, that is, a connection state of the connector 150 is determined to be in a normal state Further, the predetermined threshold time Ty may be set to between an actual dead time and allowable dead time that is permitted as the semiconductor module 104, after the actual dead time actually generated between the switching elements 11011 and 110L of the upper and lower arms is learned, and is set to a predetermined value.

As described above, the signal Vge between gate and emitter is transmitted with a delay by a time constant corresponding to resistance and capacitance on the flow path with respect to the gate signal Vg. On the other hand, when a connection state of the wiring 108 or the connector 150 is degraded due to aging of the connector 150, contact resistance Rc of the connector 150 increases. When such contact resistance Rc increases, the time constant increases by an increment amount, and a phase delay of the signal Vge between gate and emitter becomes larger with respect to the gate signal Vg. Therefore, on the basis of the magnitude of such phase delay, a state of the wiring 108 that electrically connects the control board 106 and the semiconductor module 104 via the connector 150 can be detected.

The micom 130 determines that the wiring 108 is in a normal state and the connector 150 properly electrically connects the control board 106 and the semiconductor module 104, when the delay time Tthon is determined to be within the predetermined threshold time Ty in the step 210 described above, and allows an operation as usual (step 220).

On the other hand, the micom 130 determines that the wiring 108 is not in a normal state, that is, a connection abnormality may be generated in the connector 150, when the delay time Tthon is determined to exceed the predetermined threshold time Ty in the step 210 described above, and outputs, to the display meter 132, a command for warning a vehicle occupant and calling attention to that a connection abnormality may be generated in the wiring 108 (step 230). In this case, the display meter 132 performs a warning and attention calling display according to a command from the micom 130. As an example of the display, “a connection state of the connector has changed” or “maintenance of the IPM is necessary” can be used.

Thus, in the wiring state detection device 100 of the present embodiment, the phase delay of the signal Vge between gate and emitter with respect to the gate signal Vg is detected as the delay time Tthon and a state of the wiring 108 can be detected on the basis of whether or not the delay time Tthon is within the predetermined threshold time Ty. As described above, the gate signal Vg is supplied from the micom 130 of the control board 106 toward the switching element 110 of the semiconductor module 104. The signal Vge between gate and emitter is a signal when the switching element 110 is on-driven and energization starts. The wiring 108 electrically connects the control board 106 and the semiconductor module 104 via the connector 150.

The wiring 108 can be determined to be in a normal state, when the delay time Tthon is within the predetermined threshold time Ty as shown in FIG. 5A. On the other hand, the wiring 108 can be determined to may not be in a normal state, when the delay time Tthon exceeds the predetermined threshold time Ty as shown in FIG. 5B.

Even when the delay time Tthon described above exceeds the predetermined threshold time Ty, each of the switching elements 110 can be driven, thus, the load can be operated. Accordingly, before the load operation becomes impossible, it is possible to inform a vehicle occupant through the display meter 132 that the wiring 108 or the connector 150 may not be in a normal state, that is, a failure sign of the load operation. Therefore, according to the wiring state detection device 100 of the present embodiment, before occurrence of the load operation impossibility, exchange or repair of the wiring 108 that electrically connects the control board 106 and the semiconductor module 104 via the connector 150 or the connector 150 can be urged.

Further, in the present embodiment, a current that flows to the reactor 124 is detected. Then, by means of the phase delay (that is, delay time Tthon) of the signal Vge between gate and emitter when the switching element 110 is on-driven and energization starts with respect to the gate signal Vg output from the micom 130, a state of the wiring 108 is detected.

Therefore, according to the present embodiment, it is unnecessary to amplify a voltage between both ends of the resistance with a large gain, in contrast to that uses the voltage between both ends of the gate resistance 138 for detecting a state of the wiring 108. Further, the wiring state can be prevented from being erroneously detected due to large noise generated in the IPM 102. Therefore, according to the present embodiment, a state of the wiring 108 that electrically connects the control board 106 and the semiconductor module 104 via the connector 150 can be efficiently and accurately detected.

Further, as a method for preventing erroneous detection of the wiring state from occurring due to large noise generated in the IPM 102, it is considered to use a filter having a large time constant on a flow passage of a gate signal from an output side of micom 130 to an input side of the switching element 110. However, such a method takes much time to determine a state detection of the wiring, because the signal transmission takes relatively much time.

On the other hand, in the present embodiment, it is not necessary to make a resistance value of the gate resistance 138, provided on the gate signal flow passage between the output side of the micom 130 and the input side of the switching element 110, excessively large for detecting a state of the wiring 108, and it is unnecessary to dispose a filter having a large time constant. Therefore, according to the present embodiment, the state detection of the wiring 108 can be speedily determined because the signal transmission is performed without spending so much time when a state of the wiring 108 is detected.

In the second embodiment described above, the semiconductor module 104 may be assumed as a drive unit of the present invention. Further, the control board 106 may be assumed as a control unit of the present invention. Still further, that the micom 130 measures the delay time Tthon may be assumed as a detection unit of phase delay of the present invention. The delay time Tthon is a time from an on command timing T1 when the gate signal Vg that turns on the switching element 110 is output to an on start timing T3 when the switching element 110L is switched from off to on after the signal Vge between gate and emitter transfers from a state of falling below the threshold Vth to a state of exceeding the threshold Vth. Further, that the micom 130 determines whether or not a connection state of the wiring 108 or the connector 150 is normal based on whether or not Tthon≦Ty is satisfied may be assumed as a connection state detection portion of the present invention.

In the second embodiment described above, a state of the wiring 108 can be detected when the delay time Tthon is measured, and the delay time Tthon is compared with the predetermined threshold time Ty. As described above, the delay time Tthon is a time from the on command timing T1 when the micom 130 outputs the gate signal Vg that turns on the switching element 110 to an on start timing T3 when the switching element 110L is switched from a state of off to a state of on, after the signal Vge between gate and emitter transfers from a state of falling below the threshold Vth to a state of exceeding the threshold Vth. The present invention is not limited to a configuration of the second embodiment. The delay time Tthoff from the off command timing T2 when the micom 130 outputs the gate signal Vg for an off command to the off start timing T4 is measured, and the delay time Tthoff may be compared with the predetermined threshold time Ty. The off start timing T4 is a timing when the switching element 110L is switched from on to off after a state where the signal Vge between gate and emitter exceeds the threshold Vth to a state where the signal Vge between gate and emitter falls below the threshold Vth. Still further, both of these delay times Tthon and Tthoff may be compared with the predetermined threshold time Ty.

Now, in the first and second embodiments, the IGBT is used as switching elements 20 and 110 that are the power semiconductor. However, without limiting the present invention thereto, the present invention may use a power MOSFET.

What is claimed is:

1. A wiring state detection device configured to detect a state of a wiring that detachably and electrically connects a drive unit and a control unit via a connector, the drive unit having a switching element, the control unit configured to perform drive control of the switching element, and the wiring state detection device comprising:
a phase delay detection unit configured to detect a phase delay of the drive of the switching element with respect to a command signal that the control unit supplies toward the switching element of the drive unit; and
a connection state determination unit configured to determine whether or not a connection state of the connector or the wiring is normal based on whether or not the phase delay detected by the phase delay detection unit is less than a predetermined threshold.

2. The wiring state detection device according to claim 1 wherein
the phase delay detection unit includes an output current detection unit, a comparison unit, and a delay time measuring unit,
the current detection unit is configured to detect an output current that flows to an output stage of the switching element and output the output current to the comparison unit,
the comparison unit is configured to compare the output current with a predetermined threshold current, and
the delay time measuring unit is configured to measure a time, as the phase delay, from a timing when the command signal is output to a timing when the output current becomes not less than the predetermined threshold current or not larger than the predetermined threshold current by the comparison unit.

3. The wiring state detection device according to claim 1 wherein
the phase delay detection unit includes an output current detection unit, a comparison unit, and a delay time measuring unit,
the current detection unit is configured to detect an output current that flows to an output stage of the switching element and output the output current to the comparison unit,
the comparison unit is configured to compare the output current with a predetermined threshold current and output one of a low transmission detection signal and a high transmission detection signal to the delay time measuring unit, and
the delay time measuring unit is configured to measure a time, as the phase delay, from a timing when the command signal is output to a timing when one of the low transmission detection signal and the high transmission detection signal is received.

4. The wiring state detection device according to claim 2 wherein
the output current detection unit includes a resistance that converts the output current into an output voltage,
the comparison unit is configured to compare the output voltage generated between both ends of the resistance with a predetermined threshold voltage to compare the output current with the predetermined threshold current.

5. The wiring state detection device according to claim 2 wherein
the switching element is an insulated gate bipolar transistor that has a sense emitter in which currents branched from a collector current flow.

6. The wiring state detection device according to claim 5 wherein
the output current detection unit is configured to detect a current that flows to the sense emitter as the output current.

7. The wiring state detection device according to claim 6 wherein
the output current detection unit has a sense resistance that converts the current that flows to the sense emitter into an output voltage, and
the comparison unit is configured to compare the output voltage generated between both ends of the sense resistance with a predetermined threshold voltage to compare the current flowing to the sense emitter with the predetermined threshold current.

8. An intelligent power module comprising:
a drive unit that has a switching element;
a control unit configured to perform drive control of the switching element;
a connector;
a wiring that detachably and electrically connects the drive unit and the control unit via the connector; and
a wiring state detection device that is configured to detect a state of the wiring and has a microcomputer
wherein
the microcomputer is configured to detect a phase delay of drive of the switching element with respect to a command signal that the control unit supplies toward the switching element of the drive unit, and
the microcomputer is configured to determine whether or not the connector or the wiring is in a normal connection state based on whether or not the phase delay is less than a predetermined threshold.

9. The intelligent power module according to claim 8 further comprising:
a comparison unit, wherein
the microcomputer is configured to detect an output current that flows to an output stage of the switching element and output the output current to the comparison unit,
the comparison unit is configured to compare the output current with a predetermined threshold current and output one of a low transmission detection signal and a high transmission detection signal to the microcomputer, and
the microcomputer is configured to measure a time, as the phase delay, from a timing when the command signal is output to a timing when one the low transmission detection signal and the high transmission detection signal is received.

10. The intelligent power module according to claim 9 wherein
the drive unit includes a resistance that converts the output current into an output voltage, and
the comparison unit compares the output voltage generated between both ends of the resistance with a predetermined threshold voltage to compare the output current with the predetermined threshold current.

11. The intelligent power module according to claim 9 wherein
the switching element is an insulated gate bipolar transistor that has a sense emitter in which a current branched from a collector current flows.

12. The intelligent power module according to claim 11 wherein
the microcomputer is configured to detect a current that flows to the sense emitter as the output current.

13. The intelligent power module according to claim 12 wherein
the drive unit includes a sense resistance that converts the current that flows to the sense emitter into an output voltage, and
the comparison unit is configured to compare the output voltage generated between both ends of the sense resistance with a predetermined threshold voltage to compare the current flowing to the sense emitter with the predetermined threshold current.
